(19) United States
(12) Patent Application Publication
(10) Pub. No.: US 2015/0255530 A1
(43) Pub. Date: Sep. 10, 2015

(54) MAGNETIC COUPLING AND CANCELLATION ARRANGEMENT

(71) Applicant: CAMBRIDGE SILICON RADIO LIMITED, Cambridge (GB)

(72) Inventor: Vlad LENIVE, Cambridge (GB)

(21) Appl. No.: 14/717,629

(22) Filed: May 20, 2015

Related U.S. Application Data
(62) Division of application No. 13/684,036, filed on Nov. 21, 2012.

(51) Int. Cl. H01L 49/02

(52) U.S. Cl. CPC H01L 28/10

(57) ABSTRACT

An inductor arrangement comprises a first inductor formed on a substrate, a second inductor formed on the substrate, a first loop formed on the substrate adjacent to the first inductor and a phasing network connected to the first loop which is arranged to receive an input signal representative of a flow of magnetic flux through the second inductor and to apply a first current to the first loop for generating a flow of magnetic flux for reducing magnetic coupling between the second inductor and the first inductor. A second loop can be formed on the substrate adjacent to the second inductor which is arranged to generate a second current in response to a flow of magnetic flux through the second loop, with the second current being the signal representative of a flow of magnetic flux through the second inductor.

### CROSS REFERENCE TO RELATED APPLICATIONS

This application is a Divisional of U.S. patent application Ser. No. 13/684,036, filed Nov. 21, 2012, which is incorporated herein by reference in its entirety.

### BACKGROUND

As component spacing in Integrated Circuits is reduced the problem of parasitic coupling between those components potentially becomes more significant.

Coupling between components in semiconductor device occurs via three principle mechanisms; currents propagating in the bulk semiconductor material, electrical coupling through parasitic capacitance, and magnetic coupling. The first two mechanisms have been relatively reliably addressed using N-wells, on-chip shielding, and effective grounding schemes. However, parasitic magnetic coupling has conventionally been addressed by increasing the distance between components in order to reduce the level of coupling. This is effective but limits the minimum size of devices and restricts layout choices.

Magnetic coupling may cause a number of problems such as frequency pulling, phase errors, and an increased noise level. For example, magnetic coupling between two inductors of a Quadrature Voltage-Controlled Oscillator (QVCO) tends to pull the device towards in-phase or anti-phase operation. Similar problems may arise due to magnetic coupling between the output balun of a Power Amplifier (PA) and a nearby VCO tank, or between a balun and Low Noise Amplifier load inductor.

An approach to reducing parasitic coupling of inductors is described in Jens Masuch, Manuel Delgado-Restituto “Low power 2.4 GHz quadrature generation for Body Area Network applications”, Solid-State Circuits, IEEE Journal of, vol. 45, no. 2, pp.493-496, 2010. A cancellation network electrically couples between two inductors. An electrical coupling can cause an additional load to the inductor, which can affect the Quality (Q) factor and require increased current. Also, the cancellation network requires use of lumped elements which can de-tune the tank and have to be compensated for.

The embodiments described below are not limited to implementations which solve any or all of the disadvantages of known arrangements for reducing magnetic coupling.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An aspect of the invention provides an inductor arrangement comprising: a substrate, a first inductor formed on the substrate; a second inductor formed on the substrate; a first loop formed on the substrate adjacent to the first inductor; and a phasing network connected to the first loop which is arranged to receive an input signal representative of a flow of magnetic flux through the second inductor and to apply a first current to the first loop for generating a flow of magnetic flux for reducing magnetic coupling between the second inductor and the first inductor.

In one or more embodiments, the magnetic flux generated by the first loop compensates for magnetic flux which is coupled between the second inductor and the first inductor, thereby reducing magnetic coupling between the second inductor and the first inductor.

The inductor arrangement can comprise a second loop formed on the substrate adjacent to the second inductor which is arranged to generate a second current in response to a flow of magnetic flux through the second loop and wherein the second current is the signal representative of a flow of flux through the second inductor.

The term “adjacent” can include an arrangement where the first inductor, the second inductor and the first loop are formed in one layer, with the position of the first loop being offset from the first inductor. The second loop can also be formed in the same layer, with the position of the second loop being offset from the second inductor. The term “adjacent” can include an arrangement where the first inductor is formed in one layer and the first loop is formed in a different layer, with the position of the first loop either being aligned with the first inductor, or at least partially offset from the first inductor. Similarly, the second loop can be formed in a different layer to the second inductor, with the position of the second loop either being aligned with the second inductor, or at least partially offset from the second inductor.

The phasing network can be arranged to modify phase of the first current with respect to phase of the input signal.

The phasing network can be arranged to modify amplitude of the first current with respect to amplitude of the input signal.

The phasing network can be arranged to modify a rotational direction of the first current compared to a rotational direction of the second current.

The phasing network can comprise a pair of cross-connects which are connected between respective ends of the first loop and the second loop such that a rotational direction of the first current is reversed compared to a rotational direction of the second current.

The phasing network can be arranged to perform a frequency-selective modifying of the input signal.

The phasing network can be a passive network. Alternatively, the phasing network can comprise at least one amplifier.

The phasing network can be arranged to sense the input signal and to vary a property of the first current in response to the input signal.

The phasing network can be arranged to sense a third harmonic inter-modulation product of the input signal.

The phasing network can be adjustable.

The first loop can be positioned on a side of the first inductor nearest to the second inductor and the second loop can be positioned on a side of the second inductor nearest to the first inductor.

The phasing network can be positioned between the first loop and the second loop.

The first loop can be symmetrical about a line of symmetry between a centre of the first inductor and a centre of the second inductor.

The second inductor can form part of a circuitry module with an electrical connection between the circuitry module and the phasing network for providing the signal representative of a flow of flux through the second inductor.

The second inductor can form part of a circuitry module which comprises a further inductor. The inductor arrangement can further comprise a second loop formed on the substrate adjacent to the further inductor which is arranged to generate a second current in response to a flow of magnetic flux through the second loop and wherein the second current is the signal representative of a flow of flux through the second inductor.

The inductor arrangement can be in the form of an integrated circuit.

The substrate can be a semiconductor material, such as Silicon. If a manufacturing process such as reconstituted wafer is used, then the substrate can comprise a combination of a layer of semiconductor material and an additional layer, or layers, of material.

An aspect of the invention provides a method of manufacturing an inductor arrangement on a substrate comprising: forming a first inductor on the substrate; forming a second inductor on the substrate; forming a first loop on the substrate adjacent to the first inductor; forming a phasing network connected to the first loop which is arranged to receive an input signal representative of a flow of flux through the second inductor and to apply a first current to the first loop for generating a flow of magnetic flux for reducing magnetic coupling between the second inductor and the first inductor.

An aspect of the invention provides a method of reducing magnetic coupling between a first inductor and a second inductor on a substrate, wherein a loop is provided on the substrate adjacent to the first inductor, the method comprising: receiving a signal representative of a flow of flux through the second inductor; and, applying a current to the loop for generating a flow of magnetic flux for reducing magnetic coupling between the second inductor and the first inductor.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 shows a first inductor and a second inductor mounted on a substrate;

FIGS. 2A and 2B show graphs of coupling between two inductors over a range of separation distances;

FIG. 2C shows a graph of coupling between the first inductor and the second inductor of FIG. 1 across a range of frequencies;

FIG. 3 schematically shows an arrangement according to an embodiment of the invention for reducing magnetic coupling between inductors;

FIG. 4 shows coupling between a first inductor and a second inductor or loop;

FIG. 5 shows capacitive coupling elements between a first loop and a second loop;

FIG. 6 shows coupling between the first inductor and the second inductor of FIG. 5 across a range of frequencies;

FIG. 7 shows cross-connecting elements between the first loop and the second loop;

FIG. 8 shows coupling between the first inductor and the second inductor of FIG. 7 across a range of frequencies;

FIG. 9 shows an arrangement with an alternative shape of loops;

FIG. 10 shows an arrangement where the first loop is of a different shape to the second loop;

FIG. 11 shows an arrangement with multiple loops located near victims;

FIGS. 12 and 13 show arrangements with multiple loops located near an inductor aggressor;

FIG. 14 shows an arrangement where the phasing network is arranged to sense a first current and apply a second current based on the sensed current;

FIG. 15 shows an arrangement where there is a connection between a circuitry module comprising the second inductor and the phasing network;

FIG. 16 shows a method manufacturing an inductor arrangement;

FIG. 17 shows a method of reducing magnetic coupling between a first inductor and a second inductor.

FIG. 18 shows steps of a method of reducing magnetic coupling between a first inductor and a second inductor on a substrate.

Common reference numerals are used throughout the figures to indicate similar features.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

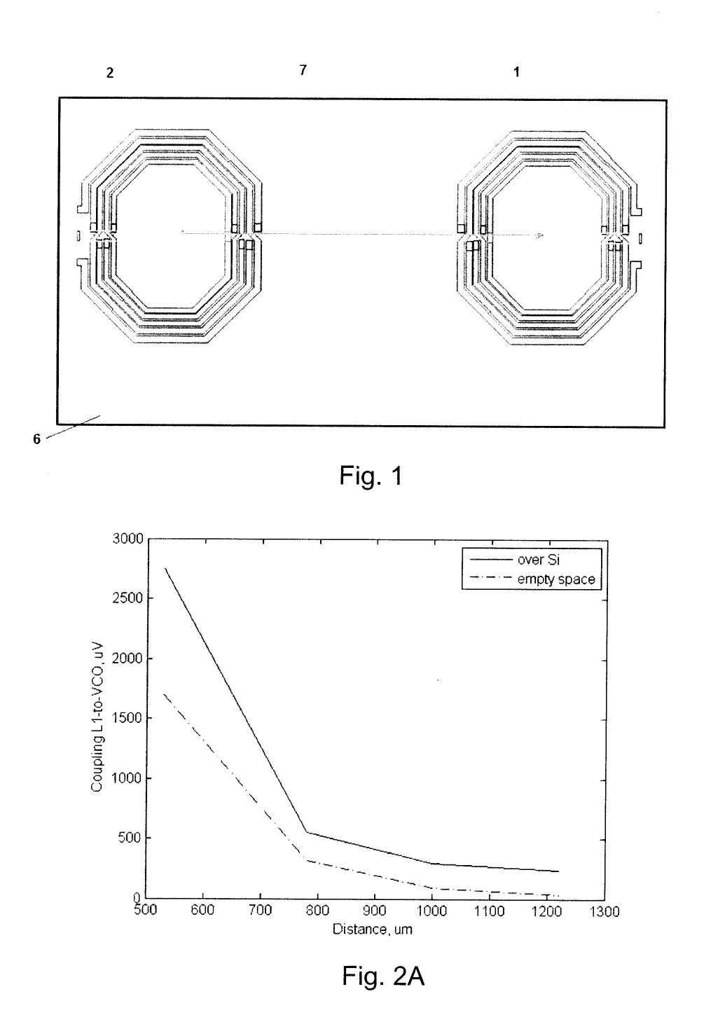

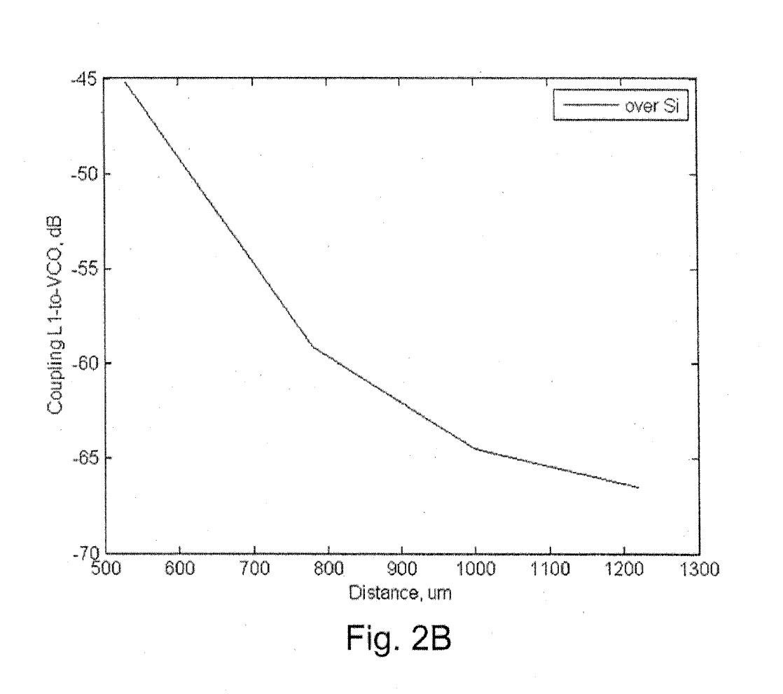

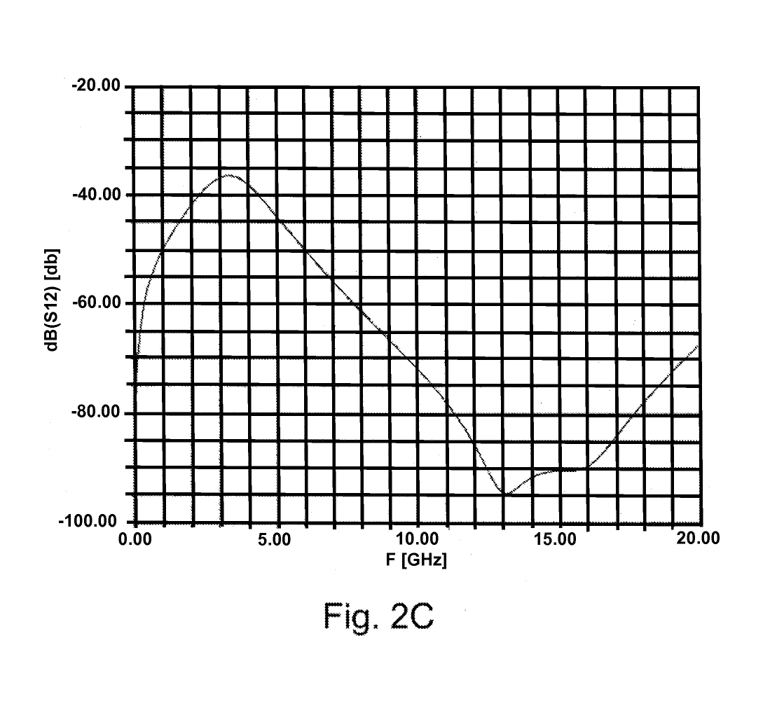

To help illustrate a problem addressed by the invention, FIG. 1 shows a typical arrangement of inductors on a Silicon substrate. A first inductor 1 and a second inductor 2 are formed on the substrate 6, and spaced apart by a separation distance 7. The inductors 1, 2 can be formed by metallised tracks deposited on the substrate 6. Conventionally, integrated circuits are manufactured on a semiconductor substrate, such as a silicon substrate. Inductors can be formed using a dedicated metal layer called Ultra-thick Metal (UTM), or any other suitable metal. More recently, there is the possibility of integrating packaging layers with Silicon which allows additional metal layers like Redistribution Layer (RDL) to be used for inductors. This is called reconstituted wafer. The inductors 1, 2 are planar devices. In integrated circuit applications, the separation distance 7 between centres of the inductors can be, for example, less than 1500 um. FIGS. 2A and FIG. 2B show coupling between a pair of inductors obtained by accurate full-wave simulation of the actual geometries and materials as used in a real Silicon chip. FIG. 2A shows coupling in Volts measured at the victim inductor with distance varying from 500 um to 1300 um. This is centre-to-centre distance, for inductors having an approximate diameter of 200 um. In FIG. 2A, a first plot shows coupling for empty space and a second plot shows coupling for inductors located over Silicon, as in real circuits. FIG. 2A shows that increasing the distance helps to reduce the cross-coupling voltage. It also shows that the coupling voltage in empty space is somewhat less compared to the same distance over Silicon, as there is no conductive path between aggressor and victim in empty space, just magnetic coupling. If the inductors are located in close proximity to Silicon, as in a real microchip, this allows for galvanic coupling between the inductors through the bulk Silicon, leading to increased coupling voltage. This also causes a change in the slope of the curve, particularly for smaller distances where the conductive path is more contributing. FIG. 2B shows the same coupling voltage measured in dB, and can be used to estimate the effects of parasitic cross-coupling to the layout. FIGS. 2A and 2B show that while there is no particular physical limit to the coupling distance, coupling effects occur for distances under 1500 micron, which is comparable to the size of the Silicon chip. FIG. 2B shows that if it is required to achieve a 20 dB reduction of coupling it is necessary to increase the centre-to-centre separation from 530 um to 1000 um (assuming no other cancellation scheme is used). Taking into account the actual sizes of two inductors, this would require an increase in the required Silicon area of at least 1.6.

Each of the inductors 1, 2 shown in FIG. 1 can be associated with a respective capacitor (not shown) to form respective LC tanks belonging to different parts of the system. Typically, a separate grounding path will be allocated for each of the tanks Despite the separate electrical grounds, parasitic magnetic coupling causes additional connection between the tanks and, consequently, between corresponding parts of the system. Simulation shows the amount of parasitic coupling depends on the proximity between the inductors, as well as the resonant frequency of each tank. FIG. 2C shows the coupling level exhibited by the pair of inductors of FIG. 1, under conditions where the two tanks are located at a separation distance of 440 um and tuned to the same frequency of 3.6 GHz. A maximum coupling of −36.3 dB occurs at this central frequency. The coupling level is measured by comparing the amplitudes of differential voltages for each tank, i.e. the differential voltage at inductor 1 and differential voltage induced at inductor 2. There are other ways of measuring coupling such as using common mode voltages.

A typical scenario for parasitic magnetic coupling includes an inductor-aggressor and an inductor-victim. An inductor-aggressor generates magnetic flux that is spreading away from the aggressor and couples to the inductor-victim, causing unwanted effects to the circuit. In embodiments of the invention, additional magnetic flux is generated in the vicinity of the inductor-victim to reduce, or cancel out, the magnetic flux of the inductor-aggressor. Advantageously, the additional flux is synchronous, i.e. same frequency, and counter-phase to the magnetic flux of the aggressor to cancel out the magnetic flux of the aggressor.

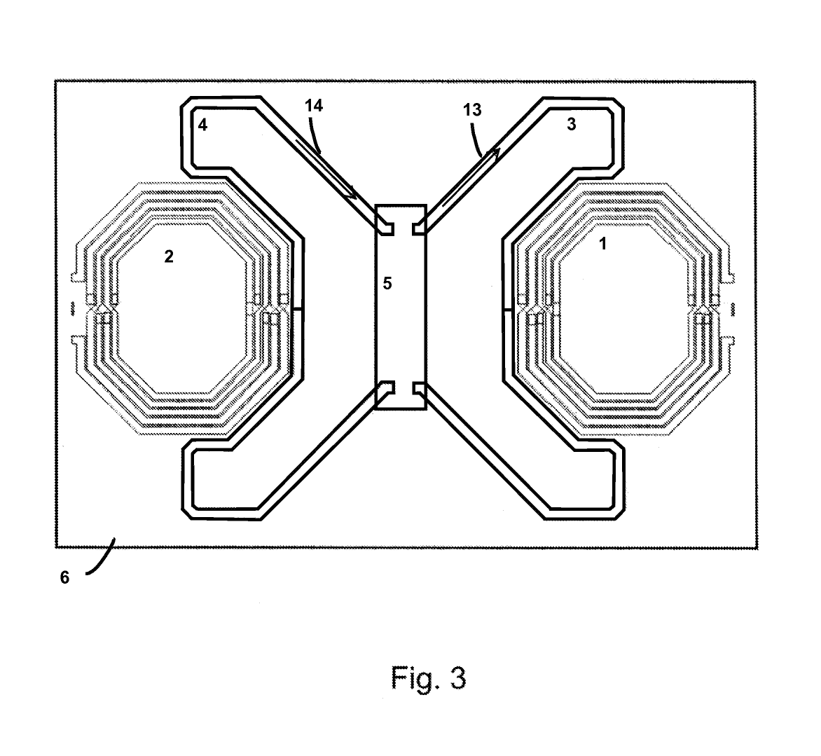

FIG. 3 shows an arrangement in accordance with an embodiment of the invention for reducing magnetic coupling between a second inductor 2 (inductor-aggressor) and a first inductor 1 (inductor-victim). A loop 3 is located in proximity to the inductor-victim 1. A loop 4 is located in proximity to the inductor-aggressor 2. Advantageously, loop 4 is located in close proximity to inductor 2 to ensure a good magnetic coupling with the inductor 2 (i.e. loop 4 couples strongly with the flux of inductor 2) and loop 3 is located in close proximity to inductor 1 to ensure there is a good magnetic coupling between the loop 3 and the inductor 1. Additional auxiliary components and/or connections can be included.

A phasing network 5 connects to the loop 3 and to the loop 4. The phasing network is arranged to receive an input signal representative of a flow of magnetic flux through the second inductor 2. In FIG. 3, this input signal is provided by a current 14 from loop 4. Loop 4 is arranged to couple to magnetic flux of the inductor-aggressor 2 and serves as a trap to sample part of the magnetic flux of the aggressor 2. Flux of the aggressor 2, flowing through the loop 4, generates a current flow 14 around the loop 4. Current 14 received from the loop 4 is applied as a current 13 to the loop 3. The loop 3 is located in proximity to inductor 1 and current flow 13 around the loop 3 is arranged to generate additional, compensating, magnetic flux which provides a reduction, or cancellation, effect to the overall resulting magnetic flux around the inductor-victim 1, thus cancelling or reducing parasitic magnetic coupling. Note that the arrangement described above provides a reduction of magnetic coupling between inductors 1, 2 without a need for any electrical/galvanic coupling between the inductors 1, 2. The loops 3, 4 and phasing network 5 are not connected to the inductors 1, 2. There are only two coupling paths: a magnetic one and a capacitive one.

The phasing network 5 can modify the current 14 received from the loop 4 before applying it as a current 13 to the loop 3. As described below, the phasing network 5 can be implemented in various ways. Phasing network 5 can modify one or more of: (i) amplitude and (ii) phase of the current received from the loop 4. Phasing network can modify amplitude and/or phase of the current received from the loop 4 in a frequency-selective manner. The phasing network can comprise phase shifting components such as any one or more elements selected from the list of capacitive elements, inductive elements and resistive elements. Additionally, or alternatively, the phasing network 5 can comprise cross-connects which have the effect of reversing the direction of current flow around the loop 3 compared to the direction of current flow around the loop 4.

It has been described how an inductor-aggressor couples with an inductor-victim. Either of the inductors 1, 2 may be the inductor-aggressor. The compensation arrangement described above is fully reciprocal as it does not contain any active circuitry and will work both ways, providing the same level of cancellation. The flux sampled by loop 4 can include part of the flux due to the inductor-victim and this can be accounted for, so it does not impair the cancellation effect.

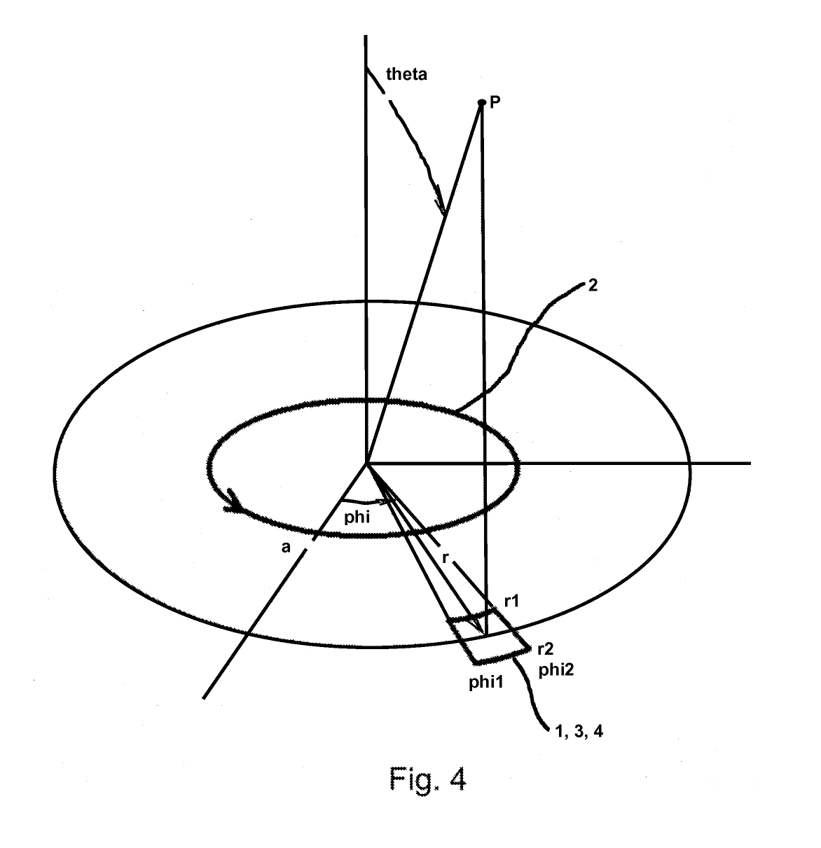

An approximate model for coupling between two inductors is shown in FIG. 4. This model has been derived from basic principles (e.g. Biot-Savart Law). An inductor (aggressor) 2 of radius a carrying the current I is located at the centre of FIG. 4. An inductor (victim) 1 is at the distance r outside the aggressor 1. Radial dimensions of inductor 1 are: r1, r2. Angular dimensions of inductor 1 are phi1, phi2.

Magnetic flux outside the aggressor 2, where r>a, is:

Full_Flux=(½)*mu*pi*I*a (1)

Magnetic flux crossing the victim 1 is:

Flux=mu*I*N/(4*pi)*A*(−(1/r2−1/r1))*(phi2−phi1) (2)

where A is the area of inductor (aggressor) and N is the number of turns of inductor (aggressor).

This model can be used to derive an approximation of an amount of flux coupled between an aggressor and a victim, and an approximation of an amount of flux that will be coupled between an aggressor (or victim) and a loop. One parameter of the loop is the area covered by the loop, which will define the angles at which the loop is visible from the centre of the inductor. In any of the embodiments, one or both of the loops 3, 4 can comprise a single turn or multiple turns. A higher number of turns increases the amount of coupling, as shown in equation (2) above.

If only one layer is available for forming the inductors 1, 2 and loops 3, 4 then each loop 3, 4 can be positioned near to, and laterally offset from, a respective inductor 1, 2. A layout of this kind is shown in FIG. 3. Positioning of the loops 3, 4 is limited by the design rules of the foundry used to form the integrated circuit. Advantageously, the track of the loop 3, 4 is located as close as possible to the track of the inductor 1, 2. The smallest gap allowed by design rules can be of the order of, for example, 2 um. The length and the width of the loop will then be based on the required coupling value. The approximate formulas above can be used to derive coupling.

If more than one layer is available for forming the inductors 1, 2 and loops 3, 4 then it is possible to stack an inductor 1, 2 and a respective loop 3, 4. The track of an inductor 1, 2 can be vertically aligned with a track of a respective loop 3, 4, although it is also possible to have some lateral offset between a position of an inductor 1, 2 on one layer and a position of a loop 3, 4 on another layer.

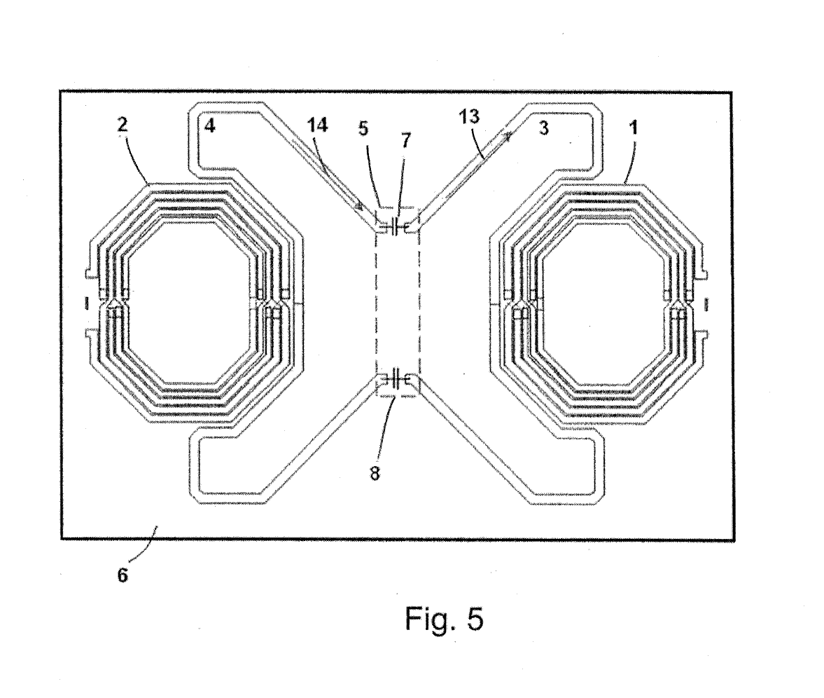

FIG. 5 shows an inductor arrangement according to an embodiment of the invention. An inductor (inductor-aggressor) 2 is located on the left-hand side, and an inductor (inductor-victim) 1 is located on the right-hand side. A pair of compensating loops comprise a loop 4 located in proximity to inductor 2 and a loop 3 located in proximity to inductor 1. A phasing network 5 is connected to the loops 3, 4 and modifies at least one parameter of current flow 13 through the coupling loop 3 compared to current flow 14 through loop 4.

In FIG. 5 the phasing network 5 comprises capacitive elements 7, 8 which are connected in series between respective ends of the loops 3, 4. Advantageously there are two capacitive elements 7, 8 as shown in FIG. 5, although it may be possible to use only one capacitive element under certain conditions. Single mode operation is desirable (i.e. to maintain only differential mode, and keep common mode to zero). For single mode operation it is desirable to maintain the symmetry of the circuit and therefore use two capacitive elements. However, there can be situations where use of a single capacitor is sufficient and does not cause significant problems with symmetry (moderate mode conversion). The inductance of the coupling loops 3, 4 is resonated-out using the additional elements 7, 8 forming the phasing network 5. This places the coupling loops 3, 4 in series resonance. Stated another way, the impedance of the loops is equal but opposite to the impedance of the capacitive element(s) of the phasing network:

X_{c}=−X_{L},

where X_{c} is impedance of the capacitive element(s) and X_{L} is impedance of the loops.

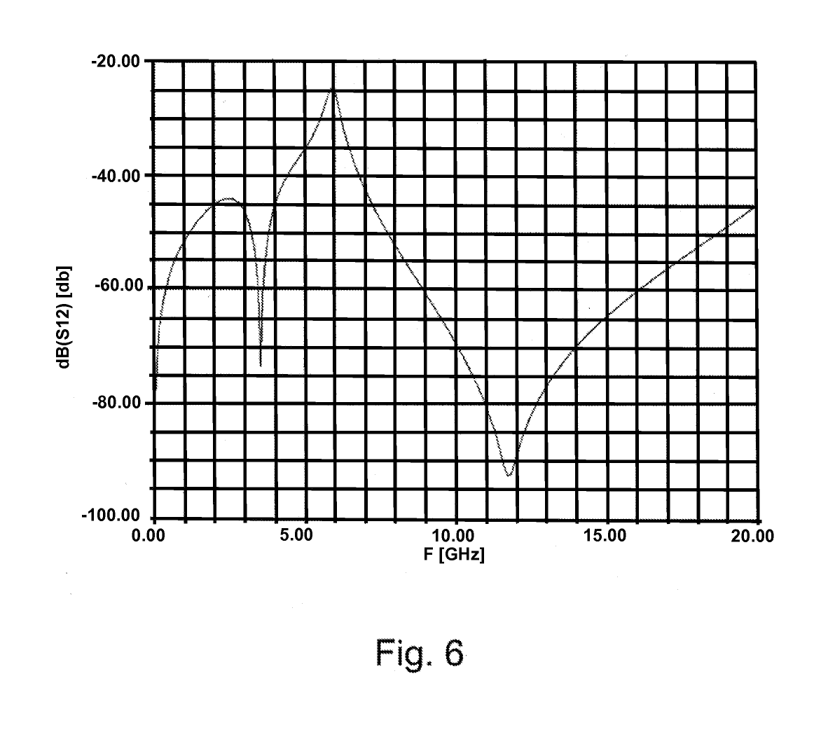

When in series resonance, the overall voltage over the circuit is minimised and current through the circuit is maximised. Magnetic coupling is a function of the current. By resonating out some, or all, elements in the coupling loops we effectively reduce the dimensions of the loop by making it more efficiently coupled. Also, at resonance, voltage and currents obey particular phase relationships and placing the circuit in resonance helps to maintain 180 degree phase shift between parts of the magnetic flux to achieve the most efficient cancellation. Referring again to FIG. 2C, without the compensating circuit the level of parasitic coupling between inductors 1, 2 is −36 dB, peaking at the resonant frequency 3.6 GHz. FIG. 6 shows coupling between the inductors 1, 2 with the compensation circuit of FIG. 5. The compensation circuit of FIG. 5 provides 30 dB cancellation of parasitic magnetic coupling at the central frequency. An advantage of this embodiment is that it can achieve deep cancellation of the aggressor flux. Some less desirable attributes are that the cancellation is relatively narrow band, and it is necessary to tune the compensation circuit.

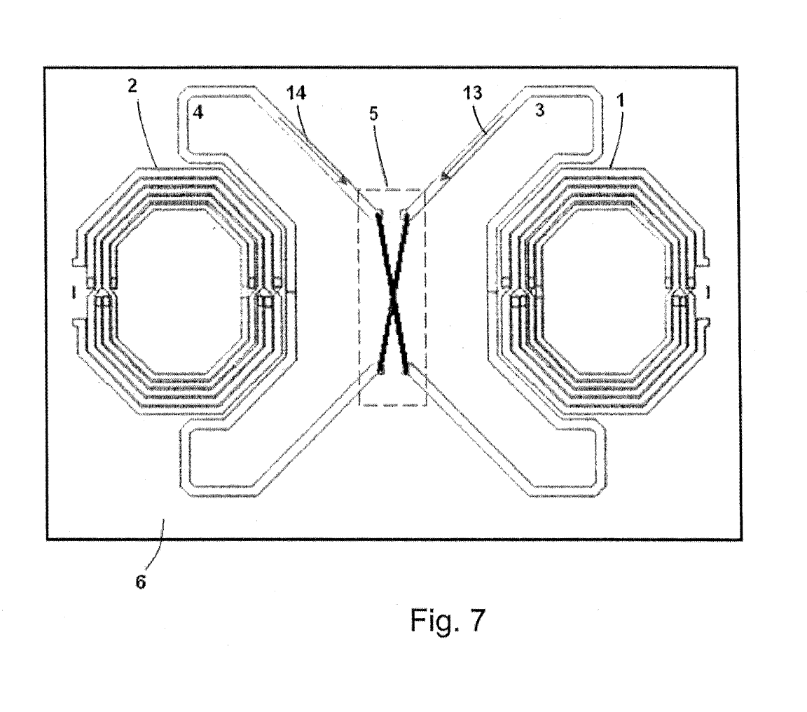

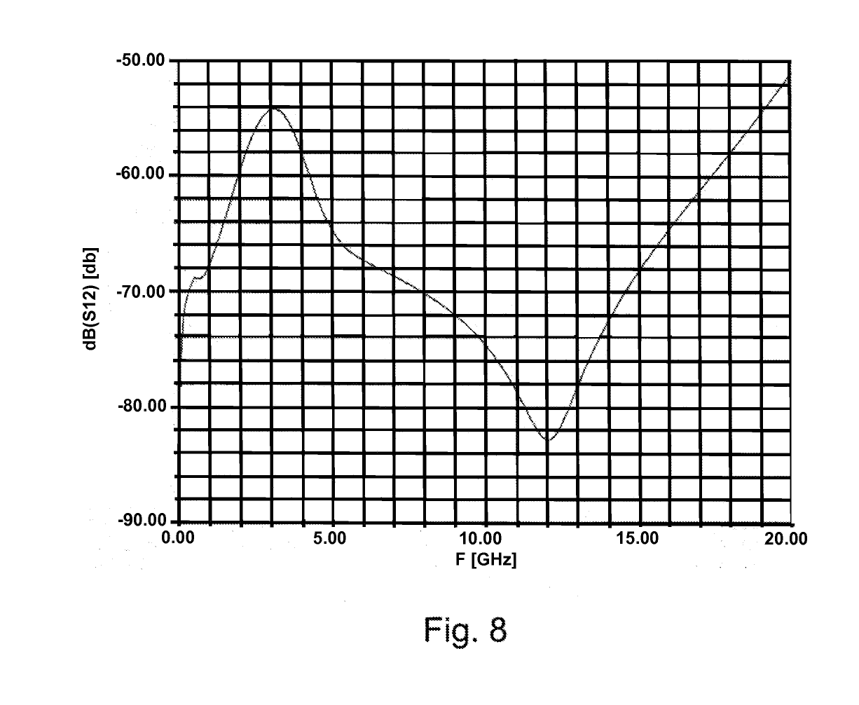

FIG. 7 shows another inductor arrangement according to an embodiment of the invention. The phasing network 5 comprises two cross connects between the loops 3, 4 to provide correct phasing of the currents in the coupling loops 3, 4. This embodiment makes use of the inductance of the coupling loops 3, 4 providing sufficient phase shift to achieve cancellation by commutating the currents in the loops 3, 4. The effect of the cross-connects is to reverse the direction of current flow through the loop 3 compared to the loop 4 and therefore cause the amount of flux sensed in loop 4 to be generated (with opposite phase) in loop 3. In FIG. 7, current 14 flows in a clockwise direction around loop 4 and current 13 flows in an anti-clockwise direction around loop 3. FIG. 8 shows coupling between the inductors 1, 2 with the compensation circuit of FIG. 7. The compensation circuit of FIG. 7 provides 20 dB cancellation of parasitic magnetic coupling at the central frequency of 3.6 GHz, as well as wideband cancellation within the 0-18 GHz frequency range. An advantage of this embodiment is that it can achieve cancellation of the aggressor flux across a wide frequency band and does not require tuning An advantage of this embodiment is that it can be less sensitive to tolerances/technology.

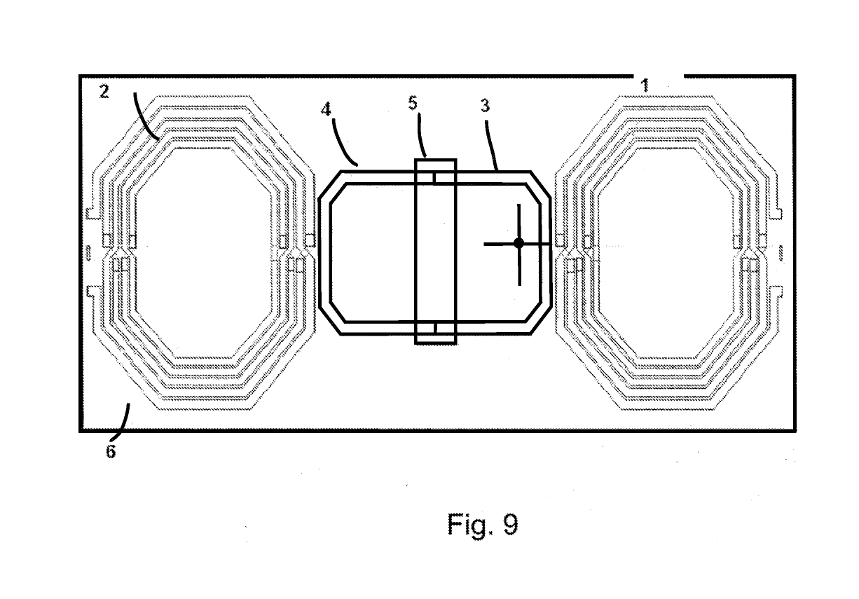

Embodiments can be realised using a variety of configurations for coupling loops 3, 4. The area covered by the loops 3, 4 and the dimensions of the loops 3,4 can adapt to the footprints of the agressor inductor and victim inductor. In FIG. 9, one loop 4 is positioned adjacent inductor 1 and another loop 3 is positioned adjacent inductor 1, but the loops do not encircle the inductors 1, 2 to the same extent as shown previously. Non-identical loops may be required in the cases where the inductors are of different size/value of inductance and/or form factor. Non-identical loops may be used in the cases where the phasing network 5 comprises active circuitry providing amplification/attenuation.

FIG. 10 shows an arrangement where the loops are of different shapes, i.e. they are not symmetrical about a line of symmetry 11 which is mid-way between the inductors 1, 2. FIG. 12 also shows a line of symmetry 12 which connects a centre of inductor 1 with a centre of inductor 2. Advantageously, the loops 3, 4 (and phasing network 5) have symmetry about this line 12 as it helps to maintain single mode operation.

In any of the embodiments, the inductors 1, 2 may be of different shape and/or relative size. The cancellation scheme can be applied to inductors which have a Figure-of-8 configuration, and to transformers/baluns.

Advantageously, the loops 3, 4 are located between the inductors 1, 2. This helps to reduce the length of the paths and minimises factors such as losses and phase shifts which would be incurred for longer connecting paths. However, it is possible to locate one of the loops 3, 4, or both of the loops 3, 4 at other positions around the inductors 1, 2. For example, loop 4 can be located on the left-hand side of inductor 2 shown in any of the Figures, which is the side remote from inductor 1. Alternatively, loop 4 can be located on the top or bottom of inductor 2 (in plan view) or at any other angular position around inductor 2. This allows some flexibility in positioning of the loops 3, 4, which may be required when other components on the substrate 6 prevent the configuration shown in the Figures.

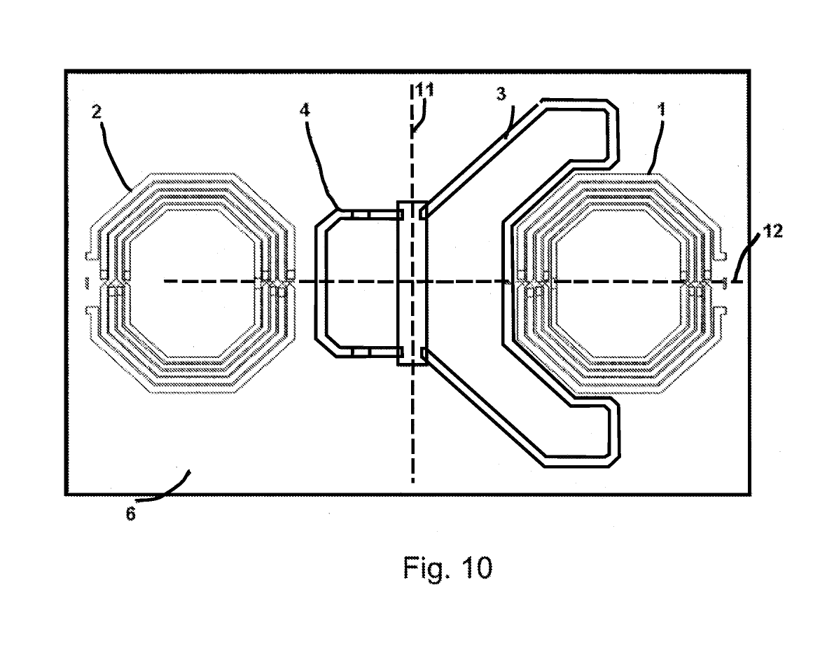

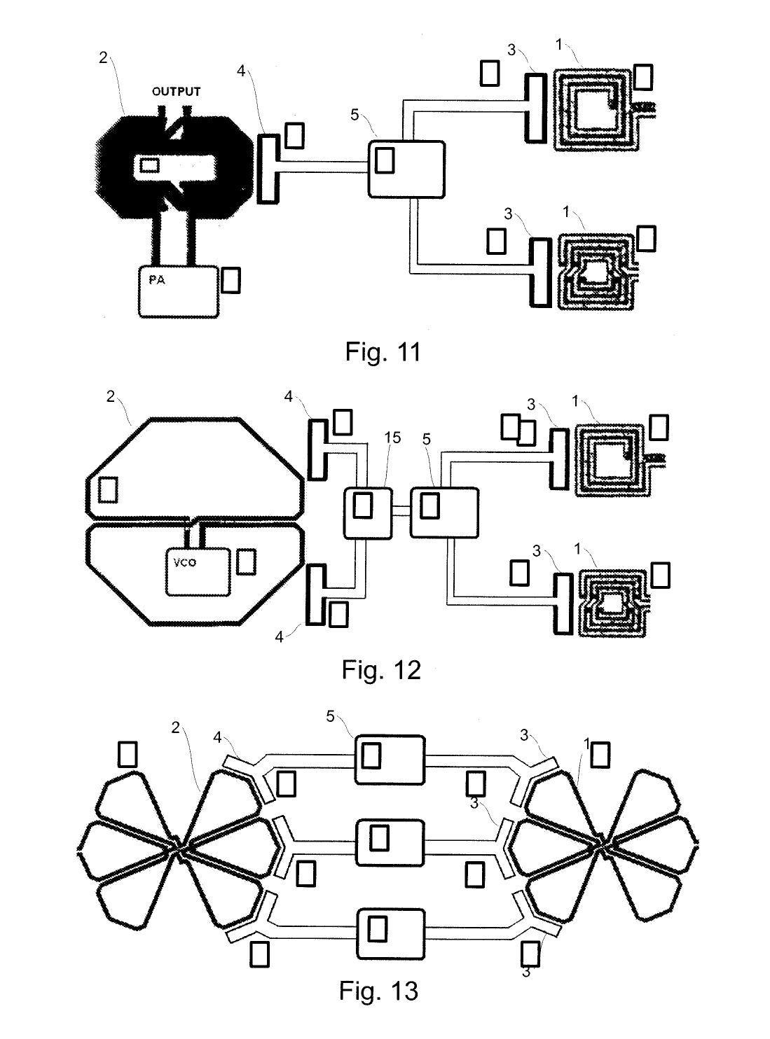

The cancellation scheme can be applied to more than two coupling loops, and to an even or odd number of coupling loops. This allows resonant cancellation at more than one frequency. FIG. 11 shows a practical application of an arrangement with more than two coupling loops. A balun 2 is connected to an output of a power amplifier (PA). An output of the balun is fed outside the integrated circuit. Two inductors 1 are located in surrounding circuits near the balun 2. Strong current circulating inside the balun 2 causes parasitic magnetic coupling to the inductors 1 of the surrounding circuitry. Coupling loop 4 in the proximity of the balun 2 provides a compensating current that is forwarded to the coupling loops 3 through the phasing network 5. This example shows a loop 3 located adjacent to each inductor 1. It will be understood that there could be any suitable number of inductors 1, each with an associated loop 3.

FIG. 12 shows an example of magnetic compensation applied to a VCO circuit comprising a Figure-of-8 inductor. A VCO typically uses large voltage swing in the tank inductor 2 to achieve the best possible phase noise. This voltage swing causes significant current through the inductor 2 that will magnetically cross-couple to the surrounding inductors 1. A pair of coupling loops 4 in the proximity of the VCO tank 2 generate currents in response to flux from inductor 2. The currents are combined in a 180-degree combiner circuit 15 and then applied to the coupling loops 3 through the phasing network 5. This example shows four coupling loops used to collect and distribute compensating signal sampled at the VCO tank 2. The currents sensed by loops 4 can be combined in any desired manner. The 180-degree combiner circuit is used in this example as the currents in each lobe of the Figure-of-8 inductor 2 are 180 degrees out of phase with one another.

FIG. 13 shows an embodiment applied to a higher order inductor structure. Order-N Inductors are a generalisation of conventional inductors and are described, for example, in U.S. patent application Ser. No. 13/312,683. A conventional inductor (e.g. FIG. 3) is an example of an order-0 inductor. A Figure-of-8 inductor is an example of an order-1 inductor. Higher order inductors are also suitable for practical usage. FIG. 13 shows a magnetic cancellation scheme for two order-3 inductors. In this example, there are three sets of apparatus. A coupling loop 4 is located adjacent one of the “lobes” of the inductor-aggressor 2 and a coupling loop 3 is located adjacent one of the lobes of the inductor-victim 1. A phasing network 5 connects to each pair of loops 3, 4. Topology and proximity of the compensating loops is selected based on the knowledge of the spatial distribution of magnetic field generated by each lobe of the order-3 inductor. In other variants, there can be a smaller (or larger) number of loops adjacent the inductor-aggressor 2 and the the inductor-victim 1.

The phasing network 5 may include elements forming a frequency-selective filter to provide necessary frequency response. The phasing network can be made adjustable to manipulate the amount of cancellation.

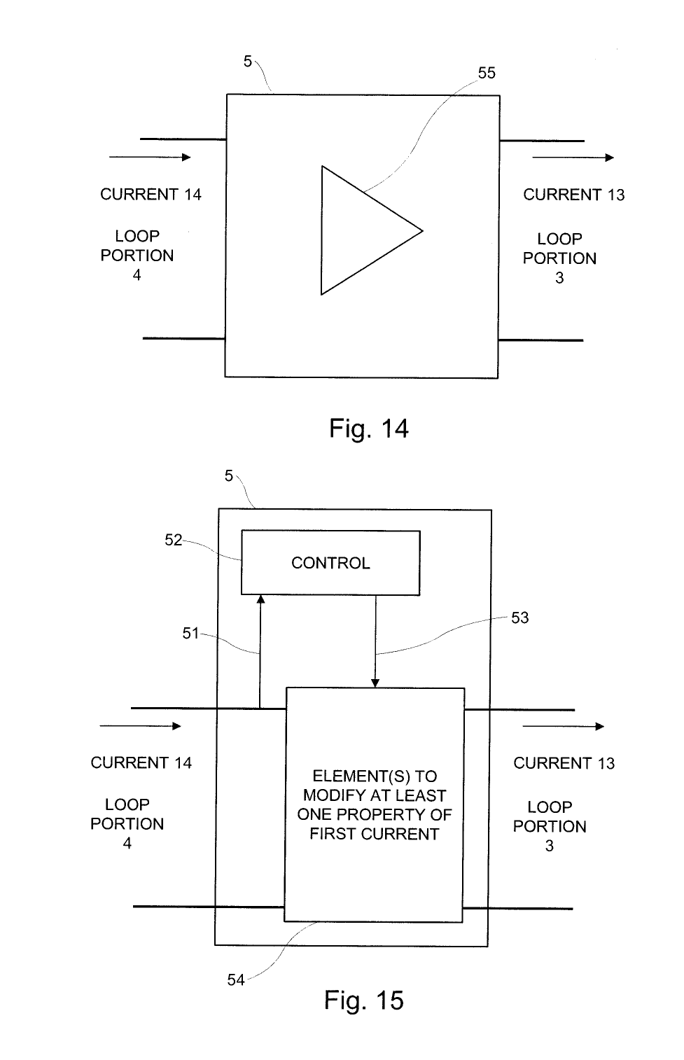

The phasing network can be an entirely passive network, which comprises passive devices such as capacitive elements and resistive elements. An advantage of a passive network is that no additional power is consumed. The phasing network may include active elements, such as an amplifier. FIG. 14 shows a phasing network 5 comprising an amplifier 55. The amplifier 55 can apply a positive gain or a negative gain (i.e. attenuation) to the current 14, or to a signal representative of a flow of magnetic flux through inductor 2. The amplifier 55 can have a gain which is fixed, or a gain which can be adjusted.

FIG. 15 shows a phasing network 5 comprising a module 52 which is arranged to sense 51 the current 14 flowing in the loop 4 and to issue one or more signals 53 to control elements 54 which can modify at least one property (e.g. amplitude, phase) of the first current to form the second current for applying to the second loop 4.

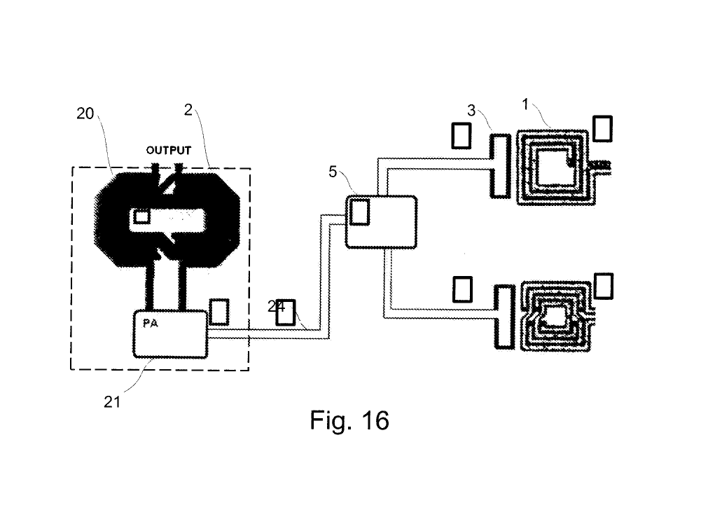

In embodiments described above an input signal to phasing network 5 is a current 14 generated by a flow of flux through a loop 4. Current 14 is representative of a flow of magnetic flux through inductor 2. In other embodiments, a signal representative of a flow of magnetic flux through inductor 2 can be provided by an electrical connection between the phasing network 5 and a circuitry module which comprises the inductor 2. Advantageously, the electrical connection is made to a component upstream of the inductor 2, and not to the inductor itself. As in the previously described arrangements, there is no direct electrical connection between the inductors 1, 2. To illustrate this, FIG. 16 shows an example of a circuitry module 20 comprising a power amplifier (PA) 21 and an output balun 2. The output balun 2 is the inductor which can interfere with inductors 1. A connection 24 is provided between the PA 21 and the phasing network 5. The PA 21 can comprise multiple stages, and any of the stages may include at least one internal balun or transformer which is separate from the output balun 2. The signal representative of a flow of magnetic flux through inductor 1 can be obtained by an electrical/galvanical connection to the PA circuitry 21, or it can be obtained using a magnetic coupling scheme which is the same as shown in earlier Figures, with a loop positioned adjacent one of the other inductors (e.g. balun/transformer) in the PA 21 rather than the output balun 2. The signal representative of a flow of magnetic flux through inductor 2 can be obtained, for example, by a splitter or divider, or a dedicated amplifier fed from the same input as the inductor 1 which serves as the aggressor. Advantageously, the input signal is as closely related to the current flowing through the inductor 2 as possible. This approach reduces the overall number of coupling loops required. The phasing network for this embodiment can be implemented as shown in FIG. 15, with the current 14 shown in FIG. 15 being replaced by the signal which is derived from the circuitry module 20. Embodiments which make use of an input signal of this kind can use any of the other features described for embodiments above.

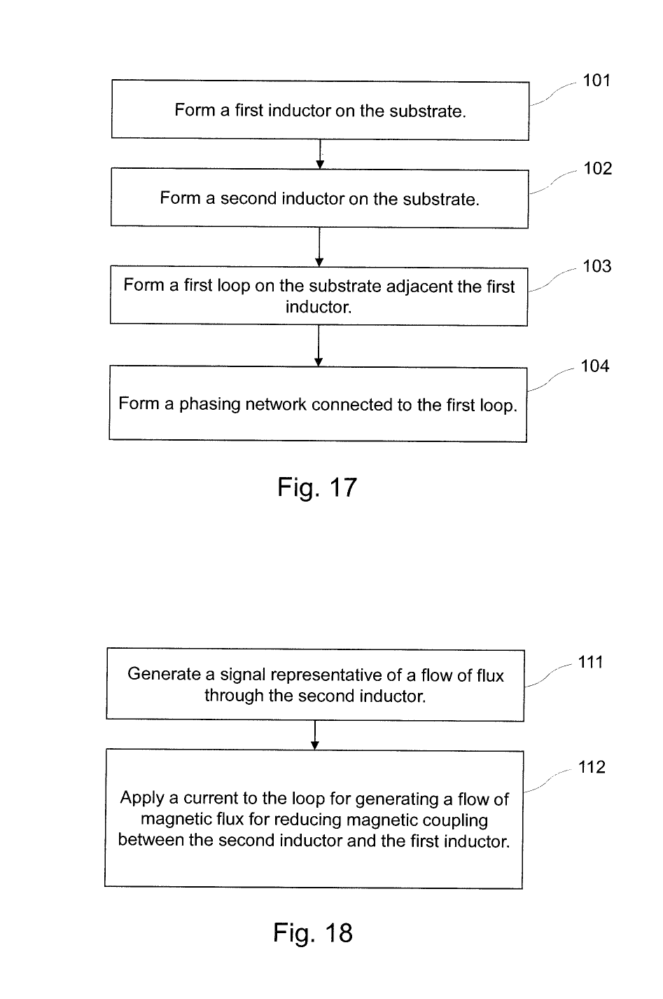

FIG. 17 shows steps of a method of manufacturing an inductor arrangement on a substrate. Step 101 comprises forming a first inductor on the substrate. Step 102 comprises forming a second inductor on the substrate. Step 103 comprises forming a first loop on the substrate adjacent to the first inductor. Step 104 comprises forming a phasing network connected to the first loop which is arranged to receive an input signal representative of a flow of flux through the second inductor and to apply a first current to the first loop for generating a flow of magnetic flux for reducing magnetic coupling between the second inductor and the first inductor.

FIG. 18 shows steps of a method of reducing magnetic coupling between a first inductor and a second inductor on a substrate. A loop is provided on the substrate adjacent to the first inductor. Step 111 comprises generating a signal representative of a flow of flux through the second inductor. Step 112 comprises applying a current to the loop for generating a flow of magnetic flux for reducing magnetic coupling between the second inductor and the first inductor.

An advantage of at least one embodiment of the invention is that it can provide a practical way of reducing parasitic magnetic coupling in densely packed layouts on Silicon.

An advantage of at least one embodiment of the invention is that it does not cause any significant impact on the performance of neither aggressor nor victim inductors. Simulations have shown that loss due to the use of the coupling loop 3, 4 is <2% of Q (i.e. not significant) due to interaction of the inductor and coupling loop.

An advantage of at least one embodiment of the invention is that it provides flexibility in realisation of phasing network—including narrow band resonant option as well as wideband option.

An advantage of at least one embodiment of the invention is that it is technology tolerant. It does not exhibit excessive sensitivity to tolerances, and can be realised on different process nodes.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

What is claimed is:

1. A method of manufacturing an inductor arrangement on a substrate comprising:
forming a first inductor on the substrate;
forming a second inductor at a location on the substrate where parasitic magnetic coupling will occur between the second inductor and the first inductor; and
forming a cancellation circuit comprising:
forming a first loop on the substrate adjacent to the first inductor; and
forming a phasing network connected to the first loop to receive an input signal representative of a flow of magnetic flux through the second inductor and to apply a first current to the first loop to generate a flow of magnetic flux to reduce or cancel the parasitic magnetic coupling between the second inductor and the first inductor.

2. A method of reducing or cancelling parasitic magnetic coupling between a second inductor and a first inductor on a substrate, the method comprising:
providing a cancellation circuit to reduce or cancel parasitic magnetic coupling between the second inductor and the first inductor, the cancellation circuit comprising a loop on the substrate adjacent the first inductor and a phasing network;
receiving, at the cancellation circuit, an input signal representative of a flow of magnetic flux through the second inductor;
applying the input signal to the phasing network;
outputting a current from the phasing network; and, applying the current output of the phasing network to the loop to generate a flow of magnetic flux to reduce or cancel the parasitic magnetic coupling between the second inductor and the first inductor.
